(19) United States
(12) Patent Application Publication
(10) Pub. No.: US 2008/0213982 A1
(43) Pub. Date: Sep. 4, 2008

(54) METHOD OF FABRICATING SEMICONDUCTOR WAFER

(75) Inventors: Young-Soo Park, Gyeonggi-do (KR); Young-Sam Lim, Gyeonggi-do (KR); Young-Nam Kim, Gyeonggi-do (KR); Dae-Lok Bae, Seoul (KR); Joon-Young Choi, Gyeonggi-do (KR); Gi-Jung Kim, Gyeonggi-do (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/039,106

(22) Filed: Feb. 28, 2008

(30) Foreign Application Priority Data
Mar. 2, 2007 (KR) 2007-21075

(51) Int. Cl. H01L 21/36

(52) U.S. Cl. 438/480; 257/E21.461

(57) ABSTRACT

Provided is a method of fabricating a semiconductor wafer. The method includes preparing a substrate wafer having a non-single-crystalline thin layer; disposing at least one single crystalline pattern adjacent to the non-single-crystalline thin layer on the substrate wafer; and forming a material layer contacting the single crystalline pattern on the non-single-crystalline thin layer.

This application claims priority to Korean Patent Application No. 10-2007-0021075, filed on Mar. 2, 2007, the disclosure of which is hereby incorporated herein by reference.

### FIELD OF THE INTENTION

The present invention relates generally to semiconductors and, more particularly, semiconductor manufacturing.

### BACKGROUND OF THE INVENTION

Since a semiconductor device using a bulk wafer as a substrate may have a large parasitic capacitance between the bulk wafer and a conductive layer disposed thereon, the semiconductor device may consume a lot of power and may operate at comparatively low speed. In order to overcome these drawbacks, a method of sequentially stacking an insulating layer and a silicon layer on a bulk wafer using silicon-on-insulator (SOI) techniques has been proposed.

Meanwhile, the silicon layer should have a single crystalline structure so that the silicon layer can be used as a channel region of a transistor. However, forming a single-crystalline silicon layer on an insulating layer using a conventional deposition technique may be technically difficult. The SOI techniques, which have been introduced to solve this technical problem, can be greatly classified into a separation by implanted oxygen (SIMOX) technique and a smart-cut technique.

The SIMOX technique involves implanting oxygen ions into a bulk wafer and annealing the resultant structure. The implanted oxygen ions react with silicon ions of the bulk wafer during the annealing process, thereby forming a silicon oxide layer to be used as the foregoing insulating layer. However, the oxygen ions implanted by the SIMOX technique may inflict damage on the silicon lattice of the bulk wafer. As a result, a wafer fabricated using the SIMOX technique may have a high defect density.

On the other hand, the smart-cut technique includes bonding a subsidiary wafer in which hydrogen ions are implanted to a bulk wafer having an insulating layer and annealing the resultant structure to separate the subsidiary wafer from the bulk wafer. In this case, since only a portion of the subsidiary wafer where the hydrogen ions exist is separated from the bulk wafer, a single crystalline portion of the subsidiary wafer remains on the insulating layer. The smart-cut technique is performed using hydrogen with a small atomic weight, thus resulting in a lower defect density compared with the SIMOX technique.

### SUMMARY OF THE INVENTION

The present invention provides a method of fabricating a wafer including forming a single crystalline semiconductor pattern on a non-single-crystalline thin layer.

Also, the present invention provides a method of fabricating a silicon-on-insulator (SOI) wafer.

According to an aspect of the present invention, there is provided a method of fabricating a wafer. The method includes preparing a substrate wafer having a non-single-crystalline thin layer. At least one single crystalline pattern is disposed adjacent to the non-single-crystalline thin layer on the substrate wafer. A material layer contacting the single crystalline pattern is formed on the non-single-crystalline thin layer.

In an embodiment of the present invention, the disposition of the single crystalline pattern adjacent to the non-single-crystalline thin layer may include coating a raw material containing a mixture of a carrier solution and a plurality of single crystalline semiconductor patterns on the non-single-crystalline thin layer; and selectively removing the carrier solution to leave the single-crystalline semiconductor patterns on the non-single-crystalline thin layer.

In another embodiment of the present invention, the single crystalline pattern may be one of polyhedrons having each side with a length of 1 mm to 5 cm. In this case, the disposition of the single crystalline pattern adjacent to the non-single-crystalline thin layer may include disposing the single crystalline pattern on the non-single-crystalline thin layer using a mechanical transfer unit.

In yet another embodiment of the present invention, the disposition of the single crystalline pattern adjacent to the non-single-crystalline thin layer and the formation of the material layer may include preparing a subsidiary wafer having at least one single crystalline pattern; disposing the subsidiary wafer on the substrate wafer such that a top surface of the single crystalline pattern is disposed adjacent to a top surface of the non-single-crystalline thin layer; forming the material layer contacting at least a portion of the single crystalline pattern on the non-single-crystalline thin layer; and separating the subsidiary wafer from the substrate wafer to leave a portion of the single crystalline pattern on the substrate wafer.

In some embodiments of the present invention, the formation of the material layer contacting at least the portion of the single crystalline pattern may be performed before separating the subsidiary wafer from the substrate wafer to leave the portion of the single crystalline pattern on the substrate wafer. In some embodiments of the present invention, the formation of the material layer contacting at least the portion of the single crystalline pattern may be performed after separating the subsidiary wafer from the substrate wafer to leave the portion of the single crystalline pattern on the substrate wafer. In this case, the single crystalline pattern may be left in a mesh shape on the substrate wafer, and the material layer may cover the single crystalline pattern left on the substrate wafer.

In some embodiments of the present invention, the preparation of the subsidiary wafer may include forming at least one separation layer. In this case, the single crystalline pattern left on the substrate wafer may be defined by the separation layer during the separation of the subsidiary wafer from the substrate wafer.

In some embodiments of the present invention, the preparation of the subsidiary wafer having at least one single crystalline pattern may farther include forming a deposition preventing pattern on the subsidiary wafer to expose an upper region of the single crystalline pattern. The deposition preventing pattern may cover a sidewall of the single crystalline pattern disposed under the separation layer and expose a sidewall and top surface of the single crystalline pattern disposed on the separation layer. According to the present invention, the deposition preventing pattern may be formed of at least one of a silicon nitride layer, a silicon oxide layer, and an organic layer.

In some embodiments of the present invention, the subsidiary wafer and the substrate wafer may be single crystalline wafers, and the non-single-crystalline thin layer may be an insulating layer. In this case, the portion of the single crystalline pattern left on the substrate wafer during the separation of the subsidiary wafer from the substrate wafer may be a single crystalline semiconductor. Also, the subsidiary wafer may differ from the substrate wafer in at least one of top-surface crystalline direction, material kind, and crystalline structure.

In some embodiments of the present invention, after separating the subsidiary wafer from the substrate wafer, the method may further include single-crystallizing the material layer using the portion of the single crystalline pattern left on the substrate wafer as a seed layer.

In some embodiments of the present invention, the disposition of the subsidiary wafer on the substrate wafer may be performed such that a distance between the single crystalline pattern and the non-single-crystalline thin layer ranges from about 1 Å to about 10 mm.

In some embodiments of the present invention, the preparation of the substrate wafer may include forming grooves in the non-single-crystalline thin layer in positions corresponding to the single crystalline patterns. In this case, the disposition of the subsidiary wafer on the substrate wafer may include inserting the single crystalline patterns into the grooves.

The formation of the material layer may include forming at least one of insulating layers and amorphous silicon (a-Si) or polycrystalline silicon (poly-Si) layers using a vapor deposition technique.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIGS. 1 through 9 are cross-sectional views illustrating a method of fabricating a wafer according to some embodiments of the present invention;

FIG. 10 is a cross-sectional view illustrating a method of fabricating a wafer according to other embodiments of the present invention;

FIG. 11 is a cross-sectional view illustrating a method of fabricating a wafer according to other embodiments of the present invention;

FIGS. 12 and 13 are cross-sectional views illustrating a method of fabricating a wafer according to other embodiments of the present invention;

FIGS. 14 and 15 are plan views illustrating a method of fabricating a wafer according to embodiments of the present invention;

FIGS. 16 through 18 are cross-sectional views illustrating a method of fabricating a wafer according to another embodiment of the present invention; and

FIG. 19 is a perspective view illustrating a method of fabricating a wafer according to yet another embodiment of the present invention.

### DETAILED DESCRIPTION OF THE INVENTION

The present invention is described more fully hereinafter with reference to the accompanying drawings, in which example embodiments of the invention are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to,” “coupled to” or “responsive to” another element or layer, it can be directly on, connected, coupled or responsive to the other element or layer or intervening elements or layers may be present. In contrast, when an element is referred to as being “directly on,” “directly connected to,” “directly coupled to” or “directly responsive to” another element or layer, there are no intervening elements or layers present. Like numbers refer to like elements throughout. As used herein, the term “and/or” includes any and all combinations (mixtures) of one or more of the associated listed items and may be abbreviated as “/”.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The structure and/or the device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, example embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

It should also be noted that in some alternate implementations, the functionality of a given block may be separated into multiple blocks and/or the functionality of two or more blocks may be at least partially integrated.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and the present application, and will not be interpreted in an idealized or overly formal sense unless expressly so defined herein.

A method of fabricating a wafer according to embodiments of the present invention includes forming at least one single crystalline pattern on a substrate wafer having a non-single-crystalline thin layer and forming a material layer contacting the single crystalline pattern on the non-single-crystalline thin layer. Here, the single crystalline pattern is formed adjacent to the non-single-crystalline thin layer. The arrangement of the single crystalline pattern adjacent to the non-single-crystalline thin layer is enabled using at least one single crystalline pattern formed on an additional wafer, using a solution containing nanoscale single crystalline particles, or using macroscopic single crystalline patterns.

According to embodiments of the present invention, the non-single-crystalline thin layer may be one of insulating layers, for example, a silicon oxide layer, which is formed on a top surface of the substrate wafer using a chemical vapor deposition (CVD) process or a thermal oxidation process.

The substrate wafer may be formed of a Group IV semiconductor material, such as silicon and germanium, a Group III-V semiconductor compound, such as GaAs, InP, and GaP, a Group II-VI semiconductor compound, such as CdS and ZnTe, or a Group IV-VI semiconductor compound, such as PbS. Also, the top surface of the substrate wafer may have one of various crystalline directions. For example, the top surface of the substrate wafer formed of a Group VI semiconductor may have a miller index of (100), (110), or (111).

In some embodiments of the present invention, the material layer contacting the single crystalline pattern may be formed of the same material as the substrate wafer. In another embodiment of the present invention, the material layer contacting the single crystalline pattern may be formed of a different material from the substrate wafer. Furthermore, the single crystalline pattern may be formed of the same material as the substrate wafer or a different material from the substrate wafer. In some embodiments of the present invention, the substrate wafer may be formed of silicon, and the single crystalline pattern and the material layer contacting the single crystalline pattern may be formed of germanium.

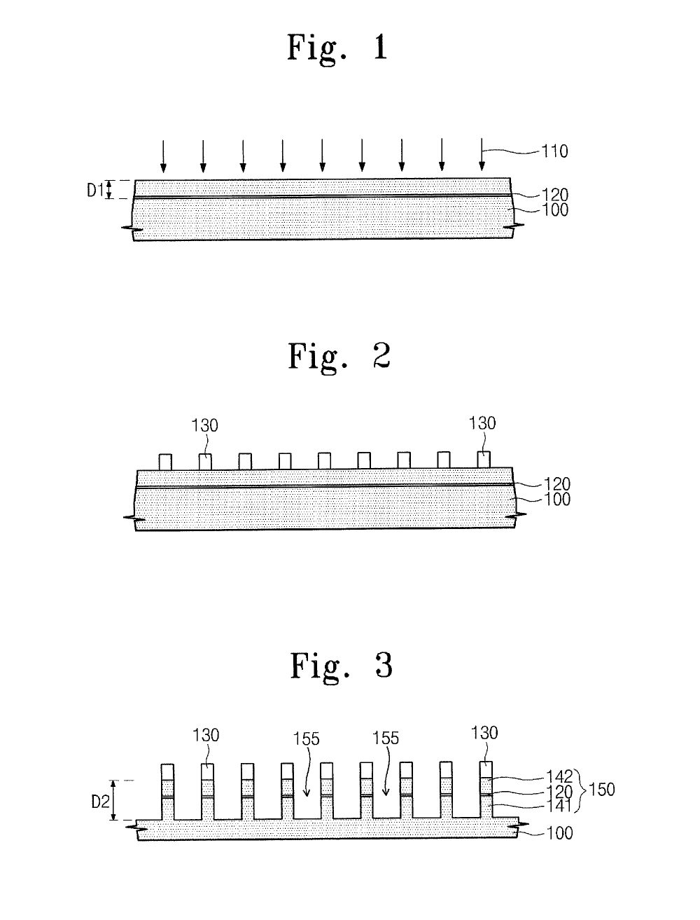

FIGS. 1 through 9 are cross-sectional views illustrating a method of fabricating a wafer according to some embodiments of the present invention. More specifically, one embodiment of the present invention is directed to a method of fabricating a wafer using at least one single crystalline pattern formed on the additional wafer. For brevity, it is assumed that each of wafers mentioned in this embodiment is a single crystalline silicon wafer having a miller index of(100). However, the crystalline direction and material kind of the wafers may be variously changed as described above.

Referring to FIG. 1, a first wafer (or a subsidiary wafer) 100 is prepared to form the single crystalline pattern. A separation layer 120 is formed at a predetermined depth D1 from a top surface of the first wafer 100. According to the present invention, the separation layer 120 may be formed using an ion implantation process 110. The separation layer 120 may be formed using hydrogen ions or other various ions.

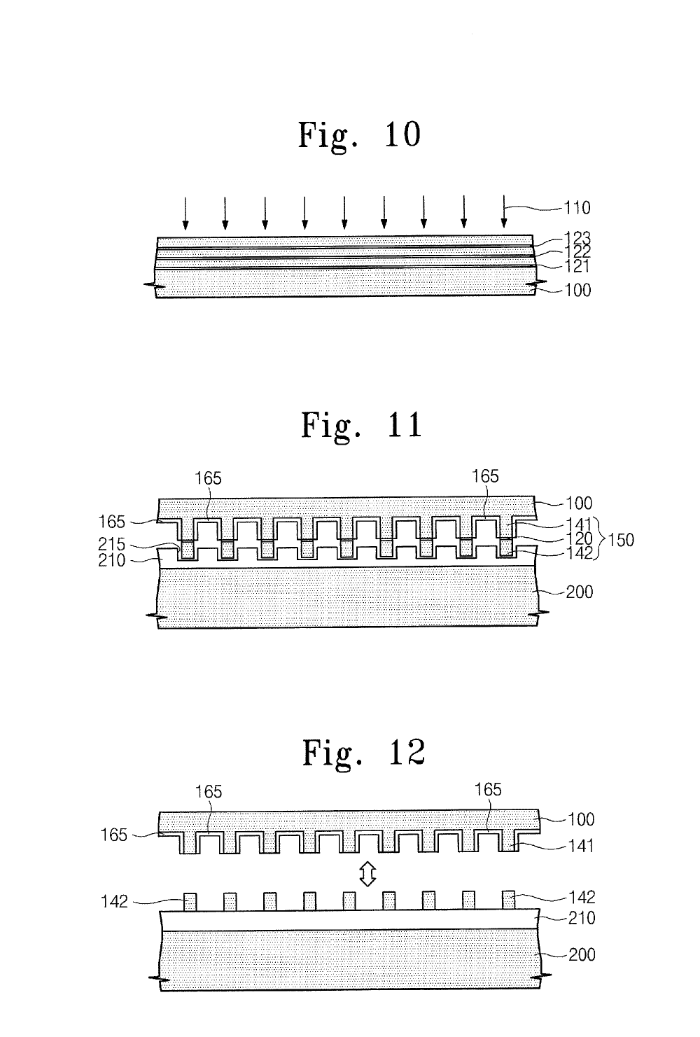

Meanwhile, according to another embodiment of the present invention, as illustrated in FIG. 10, a plurality of separation layers 121, 122, and 123 may be formed in the first wafer 100 to respectively different depths. Due to the separation layers 121, 122, and 123 formed to the different depths, the first wafer 100 can be repetitively reused during a subsequent process of forming the single crystalline pattern.

Referring to FIG. 2, at least one mask pattern 130 is formed on the first wafer 100 having the separation layer 120. The mask pattern 130 can be obtained using a photolithographic process. Also, the mask pattern 130 may be formed of at least one of a silicon oxide layer, a silicon nitride layer, and a photoresist layer.

From the plan view parallel to the top surface of the first wafer 100, a shape of the mask pattern 130 may be a polygon or a circular form. Since the mask pattern 130 will be used to define the position of the single crystalline pattern later, the single crystalline pattern will have the same shape as the mask pattern 130.

Referring to FIG. 3, the first wafer 100 is patterned using the mask pattern 130 as an etch mask, so that at least one single crystalline pattern 150 is formed to define a vent portion 155. A bottom surface of the vent portion 155 is formed at a lower level than at least the separation layer 120. That is, the vent portion 155 is formed to a depth D2 greater than a depth D1 of the separation layer 120. As a result, the single crystalline pattern 150 includes a distal part 142 disposed on the separation layer 120, the separation layer 120, and a proximal part 141 disposed under the separation layer 120.

In some embodiments of the present invention, both the mask pattern 130 and the single crystalline pattern 150 obtained using the mask pattern 130 as an etch mask are formed in an island shape as illustrated in FIG. 14, so that the vent portion 155 defined by the single crystalline pattern 150 is continuously connected. That is, the vent portion 155 is formed in a mesh shape in the entire surface of the first wafer 100. In this case, each side of the mask pattern 130 may range from 1 μm to 5 cm.

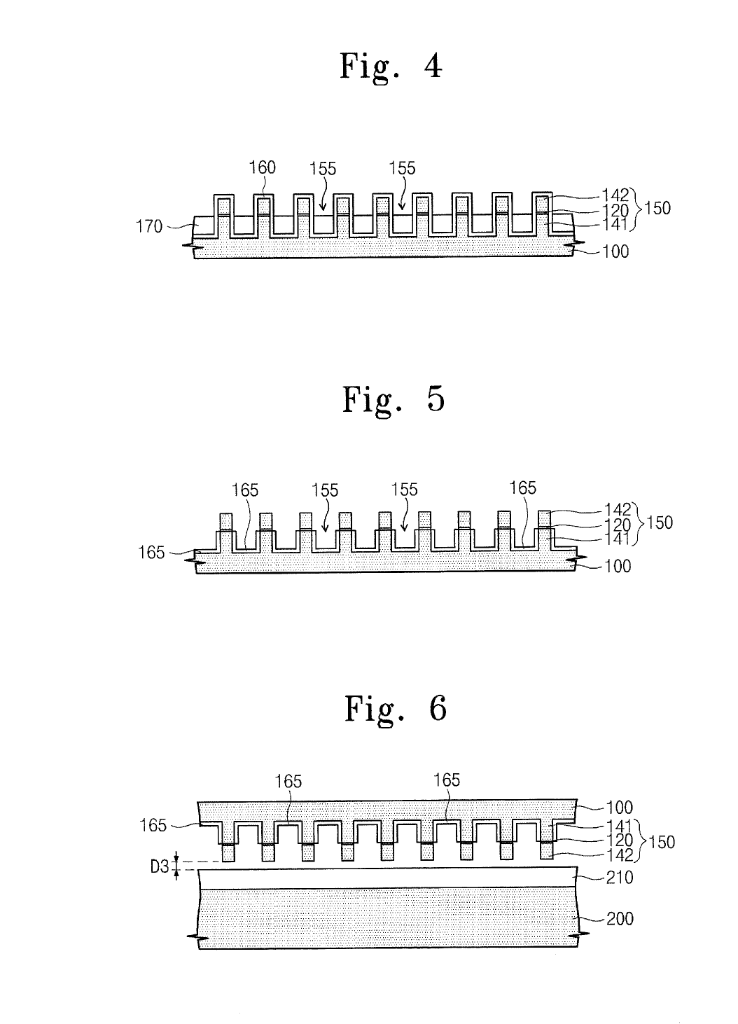

Referring to FIG. 4, a deposition preventing layer 160 is formed to cover the resultant structure having the single crystalline pattern 150. The deposition preventing layer 160 may be formed using a CVD process to a conformal thickness on the resultant structure having the single crystalline pattern 150 so that the deposition preventing layer 160 can be formed not to completely fill the vent portion 155. Also, the deposition preventing layer 160 may be formed of such a material as to minimize the deposition of a material layer on the surface of the deposition preventing layer 160 during a subsequent process of forming the material layer. In an embodiment of the present invention, the deposition preventing layer 160 may be formed of at least one of a silicon nitride layer, a silicon oxide layer, and an organic layer. The organic layer used for forming the deposition layer 160 may include a silicon carbide layer and a photoresist layer.

In another embodiment of the present invention, a surface treatment process using a deposition preventing gas may be performed on the resultant structure having the deposition preventing layer 160 to minimize the deposition of the material layer. The deposition preventing gas may contain hydrogen, nitrogen, oxygen, and argon and can be variously changed according to the kind and deposition method of the material layer.

Referring to FIG. 5, the deposition preventing layer 160 is patterned to form a deposition preventing pattern 165 exposing the distal part 142 of the single crystalline pattern 150. As a result, the deposition preventing pattern 165 is formed to cover the bottom surface of the vent portion 155 and the proximal part 141 of the single crystalline pattern 150.

The formation of the deposition preventing pattern 165 may include forming a sacrificial layer (not shown) on the deposition preventing layer 160 to fill the vent portion 155 and recessing the sacrificial layer to form a sacrificial pattern 170 filling a lower region of the vent portion 155 enclosed with the proximal part 141. As a result, the sacrificial pattern 170 is formed to expose a portion of the deposition preventing layer 160 covering the distal part 142 of the single crystalline pattern 150. Thereafter, the exposed portion of the deposition preventing layer 160 is removed, thereby completing the deposition preventing pattern 165. In this case, the deposition preventing pattern 165 is not etched due to the sacrificial pattern 170. Thereafter, the sacrificial pattern 170 is selectively removed to expose the deposition preventing pattern 165.

According to some embodiments of the present invention, the sacrificial layer may be formed of at least one material layer that minimizes the etching of the first wafer 100 and the deposition preventing layer 160 and can be selectively removed. For example, the sacrificial layer may be one of a spin on glass (SOG) layer, an organic layer, and a photoresist layer.

Referring to FIG. 6, a second wafer (or a substrate wafer) 200 having a non-single-crystalline thin layer 210 is prepared. In the illustrated embodiment, the non-single-crystalline thin layer 210 may be a silicon oxide thin layer that is obtained using a CVD process or a thermal oxidation process. However, the non-single-crystalline thin layer 210 may be another insulating layer as described above. Also, according to the illustrated embodiment, the second wafer 200 may be a single crystalline silicon wafer having a miller index of(100) as described above. However, according to other embodiments of the present invention, the crystalline direction and material kind of the second wafer 200 may be variously changed.

Thereafter, the first wafer 100 having the foregoing single crystalline pattern 150 is disposed on the second wafer 200. According to the present invention, the first wafer 100 is disposed on the second wafer 200 such that the distal part 142 of the single crystalline pattern 150 is disposed adjacent to the top surface of the non-single-crystalline thin layer 210. In this case, a distance D3 between the distal part 142 and the non-single-crystalline thin layer 210 may range from about 1 Å to about 10 mm. As is known, a minimum distance allowed between atoms is about 1 Å. Therefore, when the distance D3 between the distal part 142 and the non-single-crystalline thin layer 210 is about 1 Å, the distal part 142 is substantially in contact with the non-single-crystalline thin layer 210.

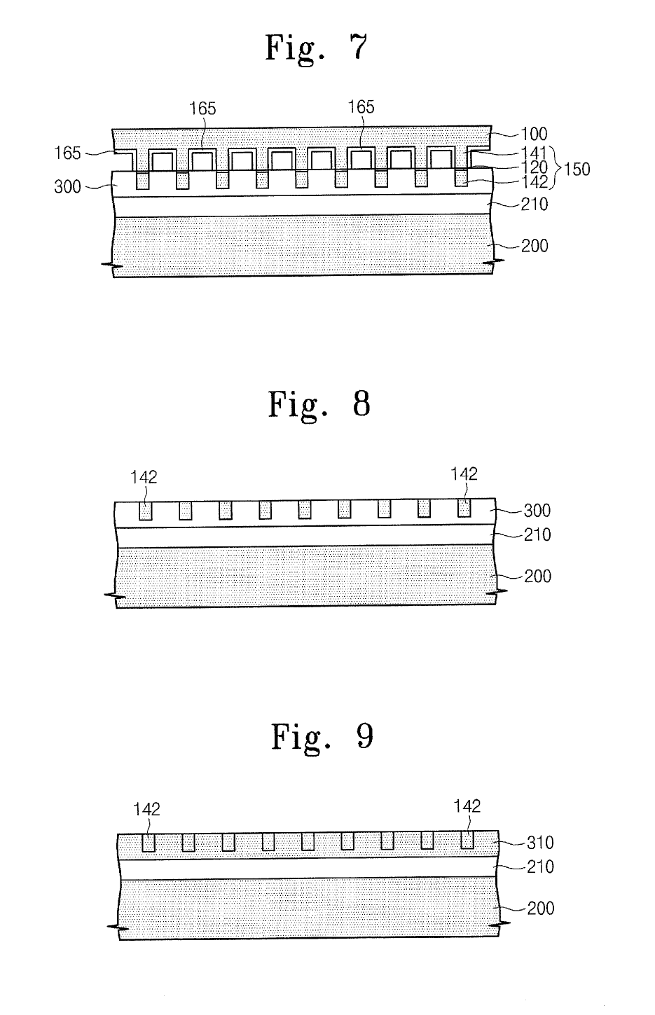

Referring to FIG. 7, a material layer 300 is formed on the non-single-crystalline thin layer 210. The formation of the material layer 300 may be performed using an epitaxial growth technique and a CVD technique. The material layer 300 may be formed of the same material as the single crystalline pattern 150 or a different material from the single crystalline pattern 150. In this case, the deposition preventing pattern 165 prevents the vent portion 155 from being filled with the material layer 300 during the deposition of the material layer 300.

In another embodiment of the present invention, the material layer 300 may be a single crystalline silicon layer obtained using a selective epitaxial growth (SEG) technique. In this case, the material layer 300 may be grown using the single crystalline pattern 150 as a seed layer.

In some embodiments of the present invention, the material layer 300 may be an amorphous silicon (a-Si) layer, a polycrystalline silicon (poly-Si) layer, or a silicon oxide layer, which is obtained using a CVD process. When the material layer 300 is an a-Si layer or a poly-Si layer, the material layer 300 has a single crystalline structure through a subsequent crystallization process using the single crystalline pattern 150 as a seed layer. In some embodiments of the present invention, before depositing the material layer 300, a predetermined annealing process may be further performed to stabilize the crystalline structure of the single crystalline pattern 150. Furthermore, when the material layer 300 is a silicon oxide layer, the material layer 300 can function as a device isolation layer for electrically isolating semiconductor devices.

According to embodiments of the present invention, the single crystalline pattern 150 is adhered to the top surface of the non-single-crystalline thin layer 21 0 using the material layer 300. That is, the material layer 300 is used as a bonding layer between the single crystalline pattern 150 and the non-single-crystalline thin layer 210. Meanwhile, process gases used for forming the material layer 300 are supplied through a region between the single crystalline patterns 150 (i.e., the vent portion 155). Since a conventional smart-cut technique does not include the vent portion 155, it is difficult to use the material layer 300 as a bonding layer.

Referring to FIG. 8, while leaving the single crystalline pattern 150 adhered to the non-single-crystalline thin layer 210 on the second wafer 200, the first wafer 100 is separated from the second wafer 200. Specifically, the first wafer 100 is separated from the second wafer 200 at the separating layer 120.

The separation of the first wafer 100 from the second wafer 200 may include annealing the resultant structure having the material layer 300. During the annealing process, the separation layer 120 in which hydrogen ions are implanted is melted so that the first wafer 100 is easily separated from the second wafer 200.

The separation layer 120 of the single crystalline pattern 150 is exposed during the separation process, thus facilitating the transmission of heat to the separation layer 120. Thus, according to the present invention, the first wafer 100 can be separated from the second wafer 200 at a lower temperature or in a shorter time than in a known smart-cut technique. Due to this low thermal budget effect, a method of fabricating a wafer according to the present invention can be effectively used to fabricate lately proposed 3-dimensional semiconductor devices. In other words, the present invention employs a low thermal budget process, thereby minimizing the damage of an internal circuit that is already formed in a lower substrate of a 3-dimensional semiconductor device.

Referring to FIG. 9, when the material layer 300 is formed of a-Si or poly-Si, a crystallization process for single-crystallizing the material layer 300 may be further performed. During the crystallization process, the single crystalline pattern 150 is used as a seed layer to single-crystallize the material layer 300.

Furthermore, according to embodiments of the present invention, a process of planarizing a top surface of the resultant structure having the material layer 300 may be further performed. The planarization process may be performed using a chemical mechanical polishing (CMP) process.

Also, predetermined portions of the single-crystallized material layer 300 and the non-single-crystalline thin layer 210 disposed thereunder may be etched, thereby exposing a top surface of a predetermined portion of the second wafer 200. In this case, since the first and second wafers 100 and 200 are different in material kind and crystalline direction as described above, the present invention can provide wafers formed of different semiconductor materials or wafers having different crystalline directions.

FIG. 11 is a cross-sectional view illustrating a method of fabricating a wafer according to other embodiments of the present invention. The illustrated embodiment is generally similar to the previous embodiments described with reference to FIGS. 1 through 9 except that a process of forming a groove in an upper region of a non-single-crystalline thin layer 210 is further performed. Thus, the same description as in the previously illustrated embodiment will be omitted for brevity.

Referring to FIG. 11, according to the illustrated embodiment, the preparation of a second wafer 200 includes forming grooves 215 in the upper region of the non-single-crystalline thin layer 210 so that single crystalline patterns 150 can be inserted into the grooves 215, respectively. The grooves 215 can be formed using photolithographic and etching processes in positions corresponding to the single crystalline patterns 150.

The area of a portion of the single-crystalline pattern 150 that faces the non-single-crystalline thin layer 210 can be increased by the groove 215. As a result, when a material layer 300 is formed between the single crystalline pattern 150 and the non-single-crystalline thin layer 210, adhesion therebetween can be increased. Also, when the single crystalline pattern 150 is inserted in the groove 215, a distance between the single crystalline pattern 150 and the non-single-crystalline thin layer 210 can be reduced. In this case, a deposited thickness of the material layer 300 used for the adhesion of the single crystalline pattern 150 with the non-single-crystalline thin layer 210 can be reduced.

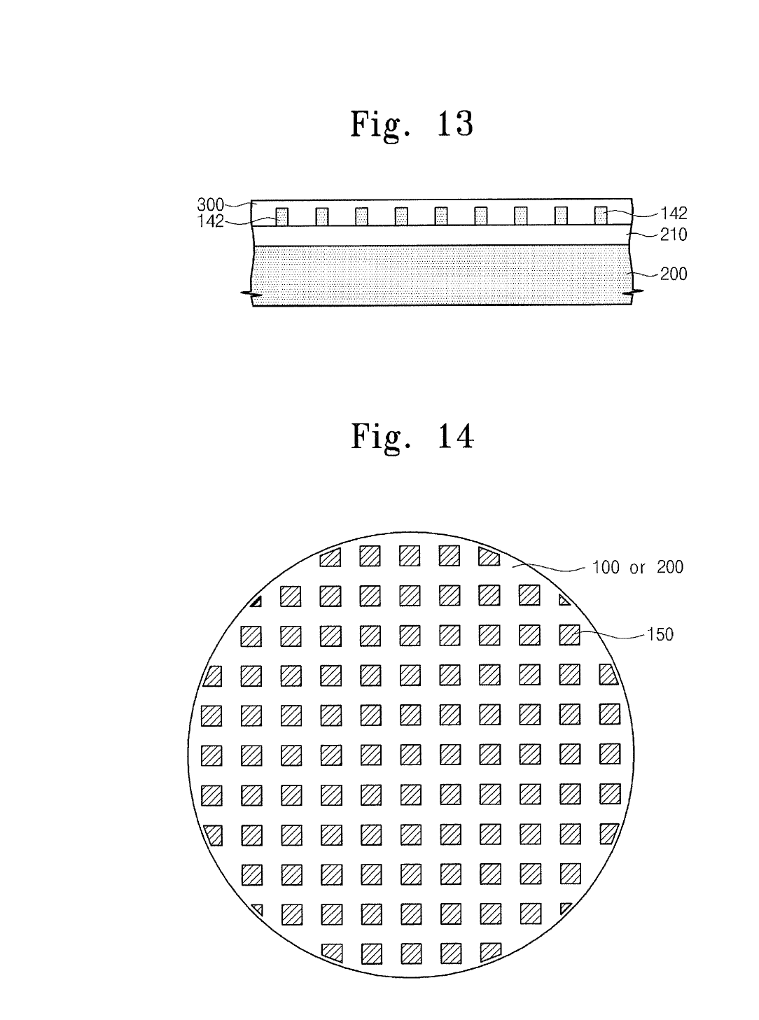

FIGS. 12 and 13 are cross-sectional views illustrating a method of fabricating a wafer according to yet another embodiment of the present invention. The illustrated embodiment is generally similar to the embodiment described with reference to FIGS. 1 through 9 except that a process of separating wafers is followed by a process of depositing a material layer. The same description as in the embodiment described with reference to FIGS. 1 through 9 will be omitted for brevity.

Referring to FIGS. 6 and 12, after disposing a first wafer 100 having a single crystalline pattern 150 on a second wafer 200, an annealing process for separating the first wafer 100 from the second wafer 200 is performed as described with reference to FIG. 8. Thus, a distal part 142 of the first wafer 100 is left on the second wafer 200, while the remaining part of the first wafer 100 is separated from the second wafer 200. As a result, the distal part 142 is directly in contact with a top surface of a non-single-crystalline thin layer 210 as illustrated in FIG. 12.

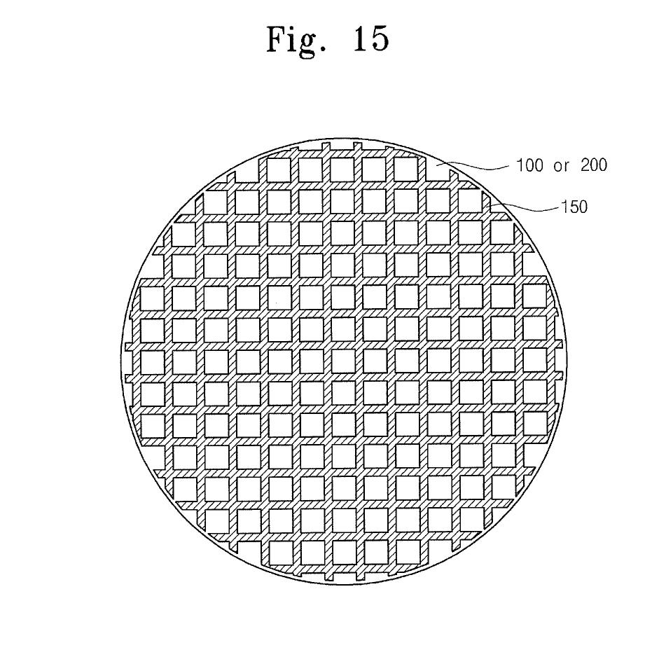

Meanwhile, when the single crystalline pattern 150 is formed in an island shape like in the previously illustrated embodiments, the separation of the first wafer 100 from the second wafer 200 may cause a technical difficulty in arranging and aligning the distal parts 142. For example, since each of the distal parts 142 is too small to selectively control its position, the distal parts 142 arranged on the non-single-crystalline thin layer 210 may have respectively different crystalline directions. In order to minimize this problem, the current embodiment may provide single crystalline patterns 150, which are connected in a mesh shape as illustrated in FIG. 15.

According to the illustrated embodiment, a process of bonding the distal part 142 to the non-single-crystalline thin layer 210 using a predetermined adhesive layer may be further performed in order to facilitate the separation of the distal part 142 from the first wafer 100. In this case, the first wafer 100 may be strained apart from the second wafer 200 during the annealing process for separating the first wafer 100 from the second wafer 200. Thus, the distal part 142 can be easily separated from the first wafer 100.

Referring to FIG. 13, the non-single-crystalline thin layer 210 and a material layer 300 covering the distal part 142 disposed thereon are formed. The material layer 300 may be formed using a CVD technique, a physical vapor deposition (PVD) technique, or an epitaxial growth technique.

The illustrated embodiment differs from the embodiment described and illustrated with reference to FIGS. 1 through 9 in that the material layer 300 is deposited on the resultant structure from which the first wafer I 00 is removed. In the embodiment described and illustrated with reference to FIGS. I through 9, uniformly supplying a process gas for forming the material layer 300 to the entire surfaces of the first and second wafers 100 and 200 may be difficult. However, according to the illustrated embodiment of FIG. 13, the material layer 300 is deposited on the resultant structure from which the first wafer 100 is removed, so that the foregoing technical problem can be solved.

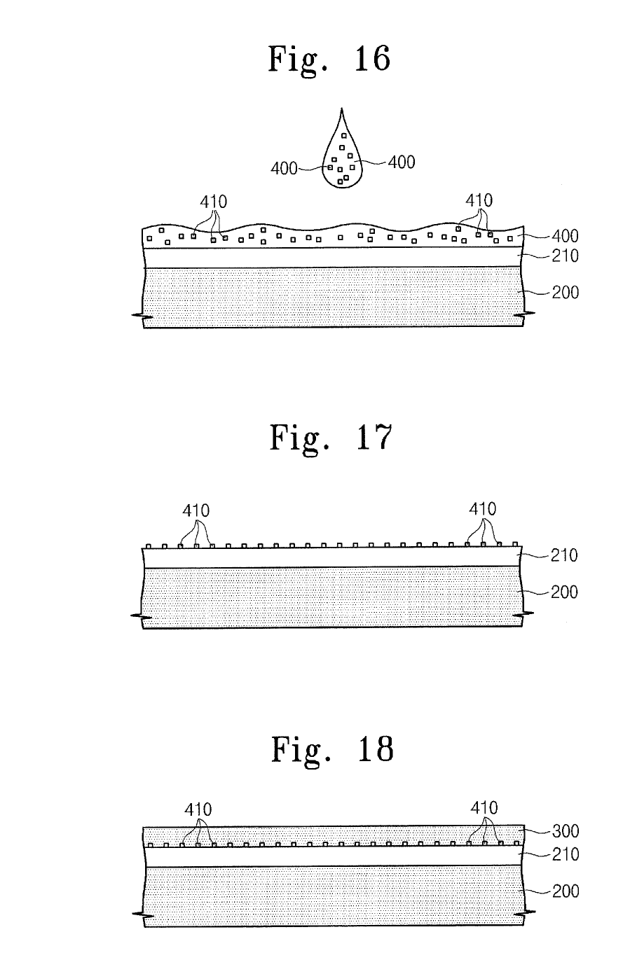

FIGS. 16 through 18 are cross-sectional views illustrating a method of fabricating a wafer according to another embodiment of the present invention. The illustrated embodiment of the present invention is directed to the above-described method of using a solution containing nanoscale single crystalline particles.

Referring to FIG. 16, according to the illustrated embodiment, a liquid raw material 400 is coated on a non-single-crystalline thin layer 210 of a second wafer 200. The raw material 400 contains a mixture of a carrier solution and single-crystalline semiconductor patterns 410. In this case, the dimension of each of the single crystalline semiconductor patterns 410 contained in the raw material 400 may range from several nm to several tens of nm. For example, the process of coating the raw material 400 may be performed using a spin coating technique, which is typically used to form a photoresist layer or an SOG layer.

Referring to FIGS. 17 and 18, the carrier solution is selectively removed. Thus, solid-phase semiconductor patterns 410 remain on the non-single-crystalline thin layer 210. The removal of the carrier solution may include evaporating the carrier solution using a predetermined annealing process.

Thereafter, a material layer 300 is deposited on the single crystalline semiconductor patterns 410. The kind and forming method of the material layer 300 may be the same as in the embodiment described with reference to FIGS. 1 through 9. Specifically, the material layer 300 may be formed using a CVD technique, a PVD technique, or an epitaxial growth technique.

Also, when the material layer 300 is formed of a-Si or poly-Si, a process of single-crystallizing the material layer 300 may be further performed. During the crystallization process, the single crystalline semiconductor patterns 410 are used as a seed layer for single-crystallizing the material layer 300. Furthermore, a process of planarizing the top surface of the resultant structure having the material layer 300 may be further performed. The planarization process may be performed using a CMP process.

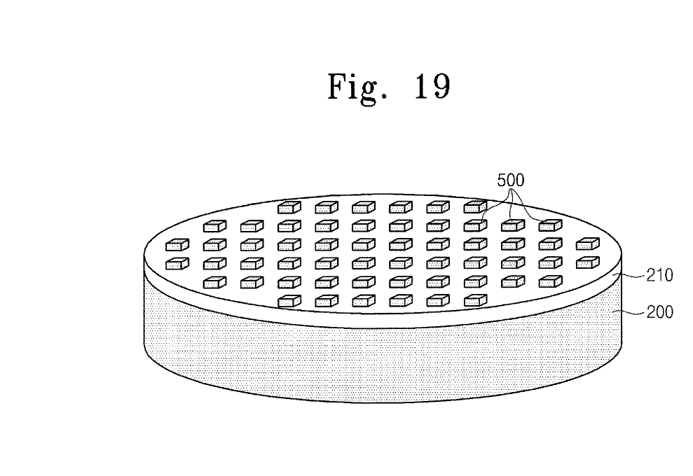

FIG. 19 is a perspective view illustrating a method of fabricating a wafer according to yet another embodiment of the present invention. The illustrated embodiment is directed to the above-described method of using macroscopic single crystalline patterns.

Referring to FIG. 19, according to the current embodiment, single crystalline semiconductor patterns 500 are disposed on a non-single-crystalline thin layer 210 of a second wafer 200 using a predetermined mechanical transfer unit (e.g., a robot arm including a vacuum suction unit). In this case, each of the single crystalline semiconductor patterns 400 may be one of polyhedrons having each side with a length of 1 mm to 5 cm.

Thereafter, a material layer is formed on the resultant structure having the single crystalline semiconductor patterns 500. In the illustrated embodiment, the material layer may be formed in the same manner as described in the previously illustrated embodiments. Also, when the material layer is formed of a-Si or poly-Si, a process of single-crystallizing the material layer may be further performed. During the crystallization process, the single crystalline semiconductor patterns 500 are used as a seed layer for single-crystallizing the material layer. Furthermore, a process of planarizing the top surface of the resultant structure having the material layer may be further performed. The planarization process may be performed using a CMP technique.

According to embodiments of the present invention, a method of fabricating a wafer includes disposing a single crystalline pattern adjacent to a non-single-crystalline thin layer (e.g., a silicon oxide layer) and forming a material layer contacting the single crystalline pattern. The single crystalline pattern can be disposed on the non-single-crystalline thin layer using the various methods described in the embodiments of the present invention, and the material layer can be single-crystallized through a crystallization process using the single crystalline pattern as a seed layer.

According to the present invention, the single crystalline pattern may differ from a substrate wafer in physical properties, such as material kind and crystalline direction. Therefore, the present invention enables the fabrication of hybrid wafers. Also, since a separation layer is exposed to a thermal source during the separation of wafers, the wafers can be effectively separated from each other at a lower temperature or in a shorter amount of annealing time than in a known smart-cut technique.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. A method of fabricating a wafer comprising:
preparing a substrate wafer having a non-single-crystalline thin layer;
disposing at least one single crystalline pattern adjacent to the non-single-crystalline thin layer on the substrate wafer; and
forming a material layer contacting the single crystalline pattern on the non-single-crystalline thin layer.

2. The method according to claim 1, wherein disposing the single crystalline pattern adjacent to the non-single-crystalline thin layer comprises:
coating a raw material containing a mixture of a carrier solution and a plurality of single crystalline semiconductor patterns on the non-single-crystalline thin layer; and
selectively removing the carrier solution to leave the single-crystalline semiconductor patterns on the non-single-crystalline thin layer.

3. The method according to claim 1, wherein the single crystalline pattern is one of polyhedrons having each side with a length of 1 mm to 5 cm,
wherein disposing the single crystalline pattern adjacent to the non-single-crystalline thin layer comprises disposing the single crystalline pattern on the non-single-crystalline thin layer using a mechanical transfer unit.

4. The method according to claim 1, wherein disposing the single crystalline pattern adjacent to the non-single-crystalline thin layer and forming the material layer comprises:
preparing a subsidiary wafer having at least one single crystalline pattern;
disposing the subsidiary wafer on the substrate wafer such that a top surface of the single crystalline pattern is disposed adjacent to a top surface of the non-single-crystalline thin layer;
forming the material layer contacting at least a portion of the single crystalline pattern on the non-single-crystalline thin layer; and
separating the subsidiary wafer from the substrate wafer to leave a portion of the single crystalline pattern on the substrate wafer.

5. The method according to claim 4, wherein forming the material layer contacting at least the portion of the single crystalline pattern is performed before separating the subsidiary wafer from the substrate wafer to leave the portion of the single crystalline pattern on the substrate wafer.

6. The method according to claim 4, wherein forming the material layer contacting at least the portion of the single crystalline pattern is performed after separating the subsidiary wafer from the substrate wafer to leave the portion of the single crystalline pattern on the substrate wafer,
wherein the single crystalline pattern is left in a mesh shape on the substrate wafer, and the material layer covers the single crystalline pattern left on the substrate wafer.

7. The method according to claim 4, wherein preparing the subsidiary wafer comprises forming at least one separation layer,
wherein separating the subsidiary wafer from the substrate wafer comprises defining the single crystalline pattern left on the substrate wafer by the separation layer.

8. The method according to claim 7, wherein preparing the subsidiary wafer having at least one single crystalline pattern comprises forming a deposition preventing pattern on the subsidiary wafer to expose an upper region of the single crystalline pattern.

9. The method according to claim 8, wherein the deposition preventing pattern covers a sidewall of the single crystalline pattern disposed under the separation layer and exposes a sidewall and top surface of the single crystalline pattern disposed on the separation layer.

10. The method according to claim 8, wherein the deposition preventing pattern is formed of at least one of a silicon nitride layer, a silicon oxide layer, and an organic layer.

11. The method according to claim 4, wherein the subsidiary wafer and the substrate wafer are single crystalline wafers, the non-single-crystalline thin layer is an insulating layer, and the portion of the single crystalline pattern left on the substrate wafer by separating the subsidiary wafer from the substrate wafer is a single crystalline semiconductor.

12. The method according to claim 11, wherein the subsidiary wafer differs from the substrate wafer in at least one of top-surface crystalline direction, material kind, and crystalline structure.

13. The method according to claim 4, after separating the subsidiary wafer from the substrate wafer, further comprising single-crystallizing the material layer using the portion of the single crystalline pattern left on the substrate wafer as a seed layer.

14. The method according to claim 4, wherein disposing the subsidiary wafer on the substrate wafer is performed such that a distance between the single crystalline pattern and the non-single-crystalline thin layer ranges from about 1A to about 10 mm.

15. The method according to claim 3, wherein preparing the substrate wafer comprises forming grooves in the non-single-crystalline thin layer in positions corresponding to the single crystalline patterns,
wherein disposing the subsidiary wafer on the substrate wafer comprises inserting the single crystalline patterns into the grooves.

16. The method according to claim 1, wherein forming the material layer comprises forming at least one of insulating layers and amorphous silicon (a-Si) or polycrystalline silicon (poly-Si) layers using a vapor deposition technique.

17. A method of fabricating a wafer comprising:
preparing a first wafer having at least one single crystalline pattern;
preparing a second wafer having a non-single-crystalline thin layer;
disposing the first wafer on the second wafer such that a top surface of the single crystalline pattern is disposed adjacent to a top surface of the non-single-crystalline thin layer;
forming a material layer contacting at least a portion of the single crystalline pattern on the non-single-crystalline thin layer; and
separating the first wafer from the second wafer to leave a portion of the single crystalline pattern on the second wafer.

18. The method according to claim 17, wherein forming the material layer contacting at least the portion of the single crystalline pattern is performed before separating the first wafer from the second wafer.

19. The method according to claim 17, wherein forming the material layer contacting at least the portion of the single crystalline pattern is performed after separating the first wafer from the second wafer,
wherein the single crystalline pattern is left in a mesh shape on the second wafer, and the material layer is formed to cover the single crystalline pattern left one the second wafer.

20. The method according to claim 17, wherein preparing the first wafer comprises forming at least one separation layer,
wherein separating the first wafer from the second wafer comprises defining the single crystalline pattern left on the second wafer by the separation layer.

21. The method according to claim 20, wherein forming the separation layer comprises implanting impurity ions into the first wafer.

22. The method according to claim 21, wherein the impurity ions constituting the separation layer contain hydrogen ions.

23. The method according to claim 21, wherein implanting impurity ions into the first wafer comprises performing ion implantation processes at least twice under different ion energy conditions such that the first wafer includes a plurality of separation layers formed at respectively different depths.

24. The method according to claim 20, wherein preparing the first wafer having at least one single crystalline pattern further comprises forming a deposition preventing pattern on the first wafer to expose an upper region of the single crystalline pattern.

25. The method according to claim 24, wherein the deposition preventing pattern covers a sidewall of the single crystalline pattern disposed under the separation layer and exposes a sidewall and top surface of the single crystalline pattern disposed on the separation layer.

26. The method according to claim 25, wherein forming the deposition preventing pattern comprises:
forming a deposition preventing layer on the first wafer having the single crystalline pattern;
forming a sacrificial layer on the deposition preventing layer;
etching back the sacrificial layer to expose the deposition preventing layer over the separation layer;
etching the exposed deposition preventing layer to form a deposition preventing pattern exposing the single crystalline pattern over the separation layer; and
removing the sacrificial layer to expose the deposition preventing pattern.

27. The method according to claim 24, wherein the deposition preventing pattern is formed of at least one of a silicon nitride layer, a silicon oxide layer, and an organic layer.

28. The method according to claim 17, wherein the first and second wafers are single crystalline wafers, the non-single-crystalline thin layer is an insulating layer, and the portion of the single crystalline pattern left on the second wafer by separating the first wafer from the second wafer is a single crystalline semiconductor.

29. The method according to claim 28, wherein the first wafer differs from the second wafer in at least one of top-surface crystalline direction, material kind, and crystalline structure.

30. The method according to claim 17, after separating the first wafer from the second wafer, further comprising single-crystallizing the material layer using the portion of the single crystalline pattern left on the second wafer as a seed layer.

31. The method according to claim 30, wherein single-crystallizing the material layer is performed using at least one of a thermal treatment technique and a laser annealing technique.

32. The method according to claim 17, after separating the first wafer from the second wafer, further comprising planarizing a top surface of the portion of the single crystalline pattern left on the second wafer and a top surface of the material layer.

33. The method according to claim 17, wherein disposing the first wafer on the second wafer is performed such that a distance between the single crystalline pattern and the non-single-crystalline thin layer ranges from about IA to about 10 mm.

34. The method according to claim 17, wherein preparing the second wafer comprises forming grooves in the non-single-crystalline thin layer in positions corresponding to the single crystalline patterns,
wherein disposing the first wafer on the second wafer comprises inserting the single crystalline patterns into the grooves.

35. The method according to claim 17, wherein forming the material layer comprises forming at least one of insulating layers and a-Si or poly-Si layers using a vapor deposition technique.

36. The method according to claim 17, wherein preparing the first wafer having at least one single crystalline pattern comprises:
forming at least one mask pattern on the first wafer;
patterning the first wafer using the mask pattern as an etch mask to form the at least one single crystalline pattern; and
removing the mask pattern to expose a top surface of the single crystalline pattern,
wherein each shape of the mask pattern and the single crystalline pattern is one of a polygon and a circular shape from a plan view parallel to the top surface of the first wafer.
